(19) United States
(12) Patent Application Publication
(10) Pub. No.: US 2009/0225251 A1
(43) Pub. Date: Sep. 10, 2009

(54) Liquid Crystal Display Device

(75) Inventors: Takuo Kaitoh, Mobara (JP); Daisuke Sonoda, Chiba (JP); Hidekazu Nitta, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd

(21) Appl. No.: 12/398,274

(22) Filed: Mar. 5, 2009

(30) Foreign Application Priority Data
Mar. 6, 2008 (JP) 2008-056718

(51) Int. Cl. G02F 1/136; H01L 33/00

(52) U.S. Cl. 349/46; 257/72; 257/E33.053

(57) ABSTRACT

In bottom-gate-type thin film transistors used in a liquid crystal display device, a channel stopper layer is formed on a poly-Si layer thus stabilizing a characteristic of the thin film transistor. The channel stopper layer is formed into a desired shape by wet etching, and the poly-Si layer is formed into a desired shape by dry etching. By applying side etching to the channel stopper layer, a peripheral portion of the poly-Si layer is exposed from the channel stopper layer, and this region is brought into contact with an n+Si layer. Due to such constitution, ON resistance of the thin film transistor can be decreased thus increasing an ON current which flows in the thin film transistor.

The present application claims priority from Japanese applications JP2008-056718 filed on Mar. 6, 2008, the content of which is hereby incorporated by reference into this application.

### BACKGROUND OF THE INVENTION

1. Field of the Invention

The present invention relates to a display device, and more particularly to a liquid crystal display device which forms pixels using thin film transistors (TFTs) as switching elements in a display region and arranges a drive circuit formed of a TFT whose channel portion is made of poly-Si on the periphery of the display region.

2. Description of the Related Art

In a liquid crystal display device, a TFT substrate on which pixel electrodes and thin film transistors (TFTs) and the like are formed in a matrix array, and a color filter substrate on which color filters and the like are formed at positions corresponding to the pixel electrodes are arranged to face each other in an opposed manner, and liquid crystal is sandwiched between the TFT substrate and the color filter substrate. Optical transmissivity of liquid crystal molecules is controlled for every pixel so as to form an image.

On the TFT substrate, data lines which extend in the longitudinal direction and are arranged parallel to each other in the lateral direction and scanning lines which extend in the lateral direction and are arranged parallel to each other in the longitudinal direction are formed, and the pixel is formed in a region surrounded by the data lines and the scanning lines. The pixel is mainly constituted of a pixel electrode and the TFT which constitutes a switching element. A display region is formed by arranging a large number of pixels having such constitution in a matrix array.

Outside the display region, a scanning line drive circuit which drives the scanning lines and a data line drive circuit which drives the data lines are arranged. Conventionally, the scanning line drive circuit and the data line drive circuit are formed by mounting an IC driver externally. This IC driver may be connected to the TFT substrate using a tape carrier method or the like or may be directly mounted on the TFT substrate using a chip-on method.

On the other hand, to satisfy a demand for the miniaturization of the whole display device while ensuring the display region or the like, a technique which forms a drive circuit on the periphery of the display region using a TFT has been developed. In such a display device, the TFT formed in the display region uses amorphous silicon (a-Si) for forming a channel portion thereof, and the TFT formed in the drive circuit part uses polysilicon (poly-Si) for forming a channel portion thereof. That is, a-Si which exhibits a small leak current is used for forming the channel portion of the TFT in the display region, while poly-Si which exhibits large mobility of electrons is used for forming the channel portion of the TFT in the drive circuit part.

In general, the TFT which uses a-Si for forming the channel portion adopts the bottom gate structure, while the TFT which uses poly-Si for forming the channel portion adopts the top gate structure. Accordingly, the TFTs which differ in structure are formed in one substrate and hence, a manufacturing process becomes complicated. JP-A-5-55570 (patent document 1) discloses a display device which is, for preventing a manufacturing process from becoming complicated, configured such that a TFT which uses poly-Si for forming a channel portion thereof also adopts the bottom gate structure. In this constitution, a poly-Si layer which constitutes a channel is firstly formed on a gate insulation film which is formed on a gate electrode and, thereafter, an a-Si layer is formed on the poly-Si layer. A contact layer which is constituted of an n+ layer is formed on the a-Si layer, and source/drain electrodes (SD electrodes) are formed on the contact layer. By allowing the TFT which uses poly-Si for forming the channel portion to adopt such constitution, the number of common processes which are shared by a TFT which uses a-Si for forming a channel portion thereof and the TFT which uses poly-Si for forming the channel portion is increased and hence, the entire process is simplified.

### SUMMARY OF THE INVENTION

In the technique disclosed in patent document 1, the poly-Si layer is formed on the gate insulation layer which is formed on the gate electrode, the a-Si layer is formed on the poly-Si layer, and the n+ layer is formed on the a-Si layer so as to form a contact layer. In such constitution, an ON current flows in the poly-Si layer which exhibits large mobility when the transistor is turned on. However, this constitution has a drawback that a leak current is generated when the transistor is turned off.

FIG. 15 shows the constitution of a TFT having a channel made of poly-Si which is substantially equal to the constitution of the TFT disclosed in patent document 1. FIG. 15A is a plan view of the TFT, and FIG. 15B is a cross-sectional view taken along a line A-A in FIG. 15A. In FIG. 15A, a poly-Si layer 107 is formed on a gate electrode 103 with a gate insulation film 104 sandwiched there between, and an a-Si layer 108 is formed on the poly-Si layer 107 in a stacked manner. An SD electrode 113 is formed on the a-Si layer 108 by way of an n+Si layer 109.

FIG. 15B shows the detailed cross section of the constitution shown in FIG. 15A. In FIG. 15B, the gate electrode 103 is formed on a background film 102, and the gate insulation film 104 is formed so as to cover the gate electrode 103. The poly-Si layer 107 is formed on the gate insulation film 104, and the a-Si layer 108 is formed on the poly-Si layer 107. The n+Si layer 109 is formed on the a-Si layer 108. The a-Si layer 108 and the n+Si layer 109 are formed by photolithography using the same mask and hence, the a-Si layer 108 and the n+Si layer 109 have the same planar shape. The SD electrode 113 is formed on the n+Si layer 109. The SD electrode 113 is constituted of a barrier metal layer 110 made of molybdenum, an aluminum layer 111 and a cap metal layer 112 made of molybdenum.

In the constitution shown in FIG. 15, by applying a plus voltage to the gate electrode 103, an ON current flows in the TFT so that the TFT is operated. However, when a zero voltage or a minus voltage is applied to the gate electrode 103 so as to turn off the TFT, there observed is a phenomenon that the TFT is not turned off. So long as such a phenomenon exists, the TFT cannot function as a switching element. The reason that such a phenomenon occurs is considered as follows.

In FIG. 15B, when the minus voltage is applied to the gate electrode 103, holes are induced in the poly-Si layer 107. There is no potential barrier between the poly-Si layer 107 and the barrier metal 110 of the SD electrode 113. Accordingly, an electric current generated by the holes directly flows in the SD electrode 113 so that the TFT is not turned off.

FIG. 16 is a cross-sectional view of a TFT which overcomes such a drawback. In FIG. 16, a poly-Si layer 107 and an a-Si layer 108 are formed on a gate electrode 103 with a gate insulation film 104 sandwiched therebetween. The a-Si layer 108 has a film thickness thereof decreased at a portion where a channel etching portion 114 is formed. A passivation film 116 made of SiN is formed so as to cover the channel etching portion 114 and the whole TFT. The constitution shown in FIG. 16 is characterized in that an n+Si layer 109 covers not only an upper surface of the a-Si layer 108 but also side portions of the a-Si layer 108 and side portions of the poly-Si layer 107. Due to such constitution, a depletion layer is formed by forming the n+Si layer 109 between the a-Si layer 108 and the SD electrode 113 as well as between the poly-Si layer 107 and the SD electrode 113 thus preventing the transmission of holes. Accordingly, the TFT having the constitution shown in FIG. 16 can prevent the increase of a quantity of an OFF current.

However, in the structure shown in FIG. 16, although the increase of a quantity of the OFF current can be prevented, there exists a drawback that a sufficient ON current cannot be acquired. That is, although the ON current flows in the poly-Si layer which exhibits large mobility, the poly-Si layer and the SD electrode are brought into contact with each other only at the side portions of the poly-Si layer. A thickness of the poly-Si layer is small, that is, approximately 50 nm. Accordingly, the contact resistance between the SD electrode and the poly-Si layer is increased thus giving rise to a phenomenon that the sufficient ON current cannot be acquired.

To increase a quantity of the ON current, it is necessary to increase a contact area between the poly-Si layer and the SD electrode. The a-Si layer shown in FIG. 16 or the like may be removed to increase such a contact area. Due to such removal of the a-Si layer, the contact area between the poly-Si layer and the SD electrode may be increased. However, when the a-Si layer is removed, the channel etching layer 114 shown in FIG. 16 cannot be formed. That is, the thickness of the poly-Si layer is 50 nm so that the formation of the channel etching layer within such a thickness range is extremely difficult.

To stabilize an operation of the TFT without forming the channel etching layer 114, a channel stopper described later may be formed. However, the formation of the channel stopper and the provision of a surface contact between the poly-Si layer and the SD electrode increase the number of photolithography steps and hence, a manufacturing cost is pushed up.

It is an object of the present invention to realize the constitution which allows a poly-Si TFT of a bottom gate type to ensure a sufficient ON current while suppressing the increase of a manufacturing cost thereof.

The present invention has been made to overcome the above-mentioned drawbacks, and it is an object of the present invention to provide a liquid crystal display device in which a bottom-gate-type TFT which forms a semiconductor layer using a poly-Si layer is configured such that a channel stopper is formed on the poly-Si layer, and an edge portion of the poly-Si layer is formed outside an edge portion of the channel stopper thus increasing a contact area between an n+Si layer and a source/drain electrode. To realize such constitution, the channel stopper layer is formed into a desired shape by wet etching, and the poly-Si layer is formed into a desired shape by dry etching. By performing side etching using the channel stopper in wet etching, it is possible to realize the above-mentioned constitution by performing a photolithography step only one time. To describe specific constitutions of the above-mentioned liquid crystal display device, they are as follows.

(1) According to one aspect of the present invention, there is provided a liquid crystal display device which includes a display region in which pixel electrodes and TFTs are formed in a matrix array, and a drive circuit which is formed on the periphery of the display region and includes a TFT therein, wherein the TFTs are configured such that a gate insulation film is formed so as to cover a gate electrode, a poly-Si layer is formed on the gate insulation film, a channel stopper layer is formed on the poly-Si layer, an n+Si layer and a source/drain electrode are formed so as to cover the channel stopper layer and a portion of the poly-Si layer, the channel layer stopper layer is formed into a desired shape by wet etching, the poly-Si layer is formed into a desired shape by dry etching, and an edge portion of the poly-Si layer formed into a desired shape by dry etching is arranged outside an edge portion of the channel stopper formed into a desired shape by wet etching.

(2) In the liquid crystal display device having the above-mentioned constitution (1), the n+Si layer is formed into a desired shape by dry etching.

(3) According to another aspect of the present invention, there is provided a liquid crystal display device which includes a display region in which pixel electrodes and TFTs are formed in a matrix array, and a drive circuit which is formed on the periphery of the display region and includes a TFT therein, wherein the TFTs are configured such that a gate insulation film is formed so as to cover a gate electrode, a poly-Si layer is formed on the gate insulation film, a channel stopper layer is formed on a main surface of the poly-Si layer except for a peripheral portion of the main surface of the poly-Si layer, an n+Si layer is in contact with the peripheral portion of the main surface of the poly-Si layer, and a source/drain electrode is formed so as to cover the n+Si layer.

(4) In the liquid crystal display device having the above-mentioned constitution (3), the n+Si layer and the source/drain electrode cover a portion of the channel stopper layer.

(5) According to still another aspect of the present invention, there is provided a liquid crystal display device which includes a display region in which pixel electrodes and pixel-use TFTs are formed in a matrix array, and a drive circuit which is formed on the periphery of the display region and includes a drive-circuit-use TFT, wherein the drive-circuit-use TFT and the pixel-use TFTs are configured such that a gate insulation film is formed so as to cover a gate electrode, a semiconductor layer is formed on the gate insulation film, a channel stopper layer is formed on the semiconductor layer, an n+Si layer and a source/drain electrode are formed so as to cover a portion of the channel stopper layer and a portion of the semiconductor layer, the channel stopper layer is formed into a desired shape by wet etching, the semiconductor layer is formed into a desired shape by dry etching, an edge portion of the semiconductor layer formed into a desired shape by dry etching is arranged outside an edge portion of the channel stopper layer formed into a desired shape by wet etching, the semiconductor layer of the drive-circuit-use TFT is formed using poly-Si, and the semiconductor layer of the pixel-use TFT is formed using a-Si.

(6) In the liquid crystal display device having the above-mentioned constitution (5), the n+Si layer is formed into a desired shape by dry etching.

(7) In the liquid crystal display device having the above-mentioned constitution (5), a film thickness of the a-Si film is 70 nm or below.

(8) According to a further aspect of the present invention, there is provided a liquid crystal display device which includes a display region in which pixel electrodes and pixel-use TFTs are formed in a matrix array, and a drive circuit which is formed on the periphery of the display region and includes a drive-circuit-use TFT therein, wherein the drive-circuit-use TFT and the pixel-use TFTs are configured such that a gate insulation film is formed so as to cover a gate electrode, a semiconductor layer is formed on the gate insulation film, a channel stopper layer is formed on a main surface of the semiconductor layer except for a peripheral portion of the main surface of the semiconductor layer, an n+Si layer is in contact with the peripheral portion of the main surface of the semiconductor layer, a source/drain electrode is formed so as to cover the n+Si layer, a semiconductor layer of the drive-circuit-use TFT is formed using poly-Si, and the semiconductor layer of the pixel-use TFT is formed using a-Si.

(9) In the liquid crystal display device having the above-mentioned constitution (8), a film thickness of the a-Si film is 70 nm or below.

(10) In the liquid crystal display device having the above-mentioned constitution (8), the n+Si layer and the source/drain electrode cover a portion of the channel stopper.

According to the constitution of the liquid crystal display device of the present invention, it is possible to realize the poly-Si TFT of a bottom gate type while maintaining a favorable ON current characteristic. Accordingly, it is possible to rationally form the drive circuit which includes the TFT in the periphery of the display region.

Further, according to the present invention, using the same process, the a-Si TFTs can be formed in the display region and the poly-Si TFT can be formed in the drive circuit region and hence, it is possible to realize the liquid crystal display device which incorporates the drive circuit in the substrate while suppressing the increase of a manufacturing cost.

Still further, according to the present invention, the channel stopper and the poly-Si layer or the a-Si layer can be formed into desired shapes respectively by performing a photolithography process one time and hence, a manufacturing cost of the TFT having the channel stopper can be reduced.

### BRIEF DESCRIPTION OF THE DRAWING

FIG. 1 is a schematic cross-sectional view showing the constitution of a portion of a liquid crystal display device of an embodiment 1;

FIG. 2A to FIG. 2C are views showing steps of a manufacturing process of the liquid crystal display device of the embodiment 1;

FIG. 3A to FIG. 3C are views showing steps of the manufacturing process of the liquid crystal display device of the embodiment 1 which follow the steps shown in FIG. 2A to FIG. 2C;

FIG. 4A to FIG. 4C are views showing steps of the manufacturing process of the liquid crystal display device of the embodiment 1 which follow the steps shown in FIG. 3A to FIG. 3C;

FIG. 5A to FIG. 5C are views showing steps of the manufacturing process of the liquid crystal display device of the embodiment 1 which follow the steps shown in FIG. 4A to FIG. 4C;

FIG. 6A to FIG. 6C are views showing steps of the manufacturing process of the liquid crystal display device of the embodiment 1 which follow the steps shown in FIG. 5A to FIG. 5C;

FIG. 7A to FIG. 7C are views showing steps of the manufacturing process of the liquid crystal display device of the embodiment 1 which follow the steps shown in FIG. 6A to FIG. 6C;

FIG. 8A and FIG. 8B are views showing steps of the manufacturing process of the liquid crystal display device of the embodiment 1 which follow the steps shown in FIG. 7A to FIG. 7C;

FIG. 9 is a view showing the detailed structure of a TFT used in the liquid crystal display device of the present invention;

FIG. 10 is a schematic cross-sectional view showing the constitution of a portion of a liquid crystal display device of an embodiment 2;

FIG. 11A to FIG. 11C are views showing steps of the manufacturing process of the liquid crystal display device of the embodiment 2 which follow the step shown in FIG. 10;

FIG. 12A to FIG. 12C are views showing steps of the manufacturing process of the liquid crystal display device of the embodiment 2 which follow the steps shown in FIG. 11A to FIG. 11C;

FIG. 13A to FIG. 13C are views showing steps of the manufacturing process of the liquid crystal display device of the embodiment 2 which follow the steps shown in FIG. 12A to FIG. 12C;

FIG. 14A to FIG. 14C are views showing steps of the manufacturing process of the liquid crystal display device of the embodiment 2 which follow the steps shown in FIG. 13A to FIG. 13C;

FIG. 15 is a view showing the structure of a TFT used in a conventional liquid crystal display device;

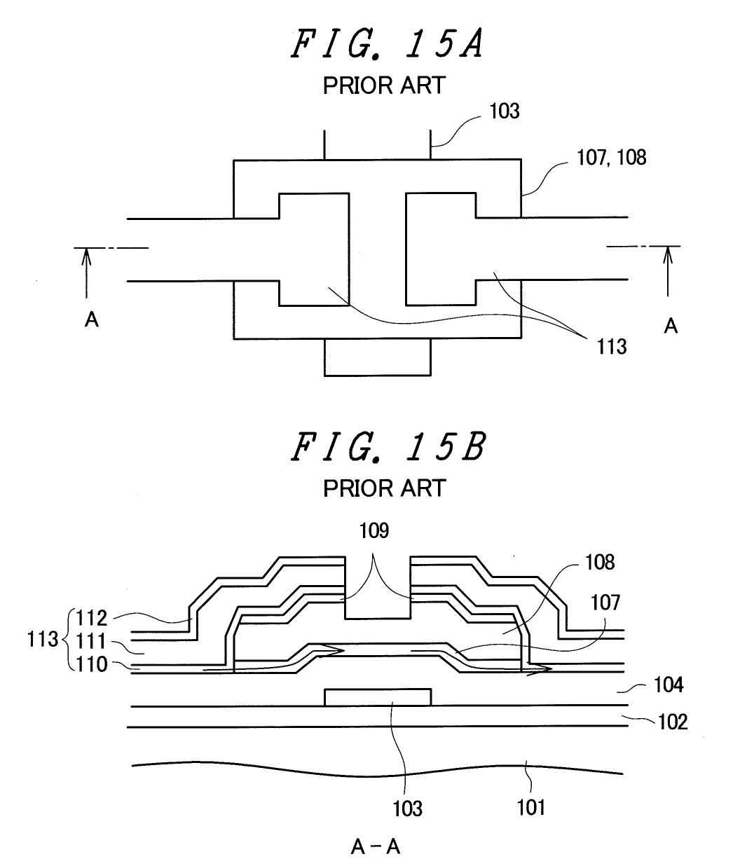

FIG. 16 is a view showing the structure of a TFT which can cope with an OFF current.

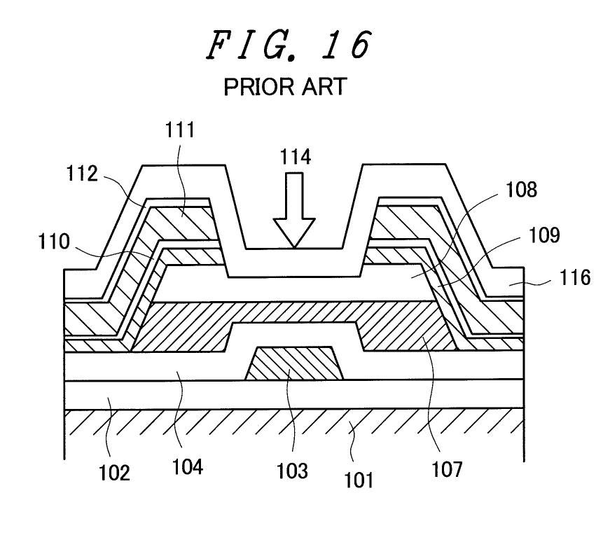

### DESCRIPTION OF THE PREFERRED EMBODIMENTS

The present invention is explained in detail in conjunction with embodiments.

### Embodiment 1

A liquid crystal display device of this embodiment includes a plurality of pixels each of which is formed in a region surrounded by video signal lines which extend in the longitudinal direction and are arranged parallel to each other in the lateral direction and scanning signal lines which extend in the lateral direction and are arranged parallel to each other in the longitudinal direction, wherein a pixel electrode and a TFT for switching are arranged in each pixel. The pixels each of which includes the pixel electrode and the TFT are arranged in a display region in a matrix array. On the periphery of the display region, a drive circuit which controls the supply of video signals to the respective pixels is arranged. In this embodiment, both of the TFT used in the pixel (pixel-use TFT) and a TFT used in the drive circuit (drive-circuit-use TFT) are formed using a bottom-gate-type poly-Si TFT. Here, the poly-Si TFT is a TFT in which a semiconductor is formed using poly-Si.

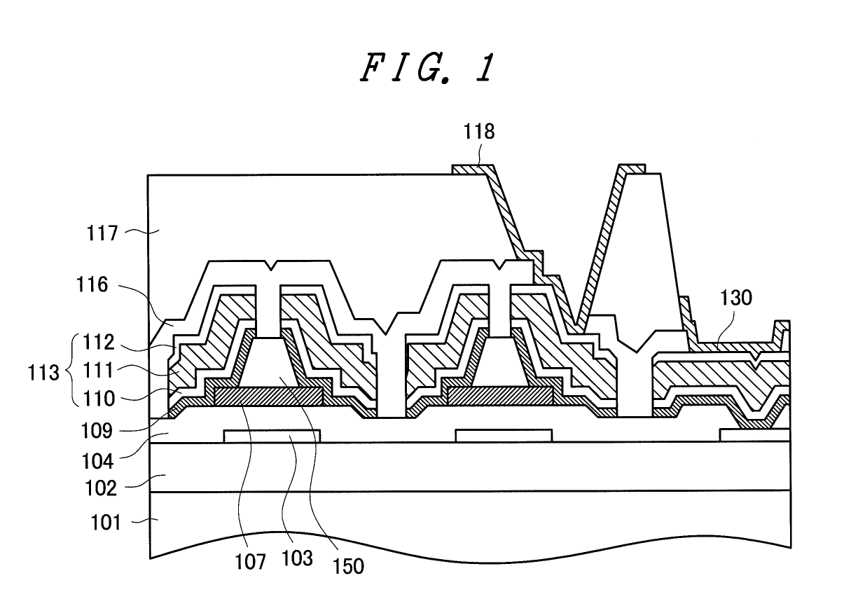

FIG. 1 is a schematic cross-sectional view showing the constitution of a portion of the liquid crystal display device of the present invention. In FIG. 1, the left-side TFT is a drive-circuit-use TFT, and the right-side TFT is a pixel-use TFT. Both TFTs are formed of a bottom-gate-type TFT in which the semiconductor is formed using poly-Si.

A terminal part is formed on a further right side of the pixel-use TFT. In FIG. 1, to make a clear comparison of the drive-circuit-use TFT, the pixel-use TFT and the terminal part, these elements are described such that these elements are arranged adjacent to each other. However, in an actual display device, the respective elements are formed remote from each other.

In FIG. 1, a background film 102 is formed on the TFT substrate 101. Although the background film 102 is formed of a single SiN film layer in this embodiment, the background film 102 may be formed of a two-layered film consisting of the SiN film and an SiO2 film. Gate electrodes 103 are formed on the background film 102. A gate insulation film 104 is formed so as to cover the gate electrodes 103. Poly-Si layers 107 are formed on the gate insulation film 104. The poly-Si layer 107 constitutes a channel portion of the TFT. A film thickness of the poly-Si layer 107 is approximately 50 nm.

A channel stopper 150 is formed so as to cover the poly-Si layer 107 which constitutes the channel portion of the TFT. The channel stopper 150 protects the channel portion of the TFT so as to make the characteristic of the TFT stable. An n+Si layer 109 is formed so as to cover the channel stopper 150 and the poly-Si layer 107. The n+Si layer 109 is provided to decrease a quantity of an OFF current.

A source/drain electrode (SD electrode) 113 is formed so as to cover the n+Si layer 109. The SD electrode 113 is constituted of a barrier metal layer 110 made of molybdenum, an aluminum layer 111 and a cap metal layer 112 made of molybdenum. As shown in FIG. 1, in this embodiment, the n+Si layer 109 and the poly-Si layer 107 are brought into face contact with each other thus reducing the contact resistance therebetween whereby a quantity of an ON current can be increased. The whole TFT is protected by a passivation film 116 made of SiN. A leveling film formed of an organic film 117 is formed on the passivation film 116 so as to level a portion of the TFT where a pixel electrode 119 is formed.

In FIG. 1, on the right side of the drive-circuit-use TFT, the pixel-use TFT is described. In this embodiment, the semiconductor layer of the pixel-use TFT is also made of poly-Si. Accordingly, in this embodiment, both of the pixel-use TFT and the drive-circuit-use TFT has the same constitution. The SD electrode 113 of the pixel-use TFT is made conductive with the pixel electrode 119 so as to enable the supply of a data signal to the pixel part. That is, a through hole 115 is formed in the passivation film 116 and the leveling film formed of the organic film 117 which cover the pixel-use TFT, and the pixel electrode 119 and the SD electrode 113 are made conductive with each other via the through hole 115. The pixel electrode 119 is formed of a transparent conductive film made of ITO.

In FIG. 1, the terminal part is described on a further right side of the pixel-use TFT. In FIG. 1, a terminal-part-use line is formed on the same layer as the SD electrode 113. That is, the terminal-part-use line is simultaneously formed with the SD electrode 113 using the same material as the SD electrode 113. A periphery of the terminal part is protected by the passivation film 116 and the organic film 117 which constitutes the leveling film. In the terminal part, the passivation film 116 and the organic film 117 are removed at a contact hole 118 in the terminal part for establishing the connection between the terminal part and an external circuit.

The terminal-part-use line is made of metal and hence, the terminal-part-use line is liable to be corroded due to an external environment. To prevent the corrosion of the terminal-part-use line, the terminal part is covered with a metal-oxide conductive film 130. To be more specific, ITO is used for forming the metal-oxide conductive film 130, and the metal-oxide conductive film 130 of the terminal part made of ITO is simultaneously formed with the pixel electrode 119 which is also made of ITO.

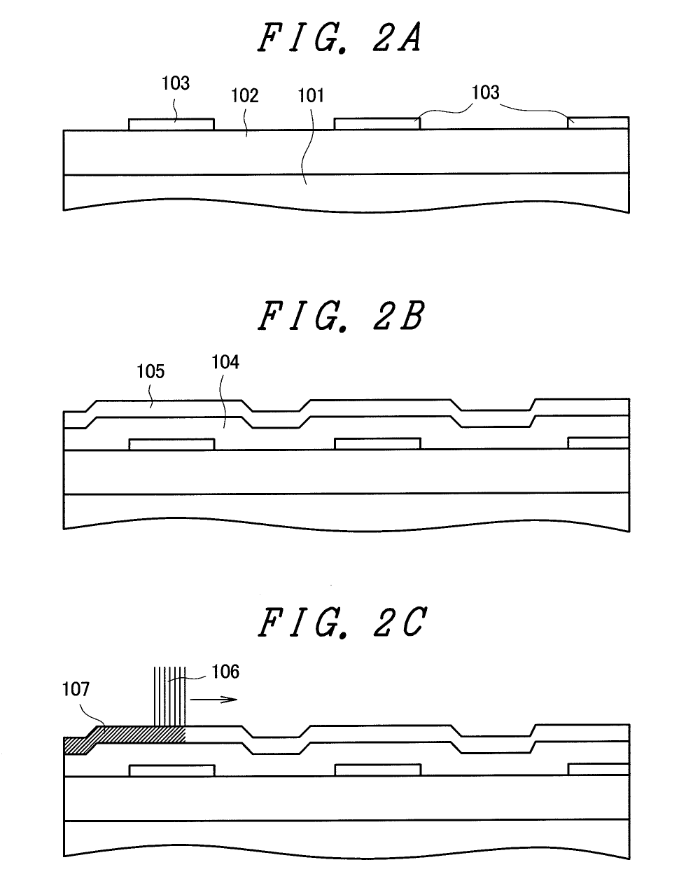

FIG. 2A to FIG. 8B show a process of forming the TFTs and the terminal part shown in FIG. 1. As shown in FIG. 2A, the background film 102 made of SiN is formed on the TFT substrate 101 by a plasma CVD method. There after, a line layer for forming the gate electrode 103 is formed as a film by sputtering, and the line layer is formed into a desired shape by a photolithography step. The gate electrode 103 is formed using a high-melting-point material (Mo-based material) by taking a laser annealing step performed following this step into consideration.

As shown in FIG. 2B, an SiO2 film for forming the gate insulation film 104 is formed by a plasma CVD method and, subsequently, an a-Si film is formed by a plasma CVD method. The a-Si film is transformed into a poly-Si film by laser annealing. For applying laser annealing to the a-Si film, dehydrogenation processing (annealing at a temperature of 450° C. or more) is performed thus removing hydrogen in the a-Si film. As shown in FIG. 2C, a-Si is transformed into poly-Si by laser beams 106 generated by a solid laser which performs continuous oscillations.

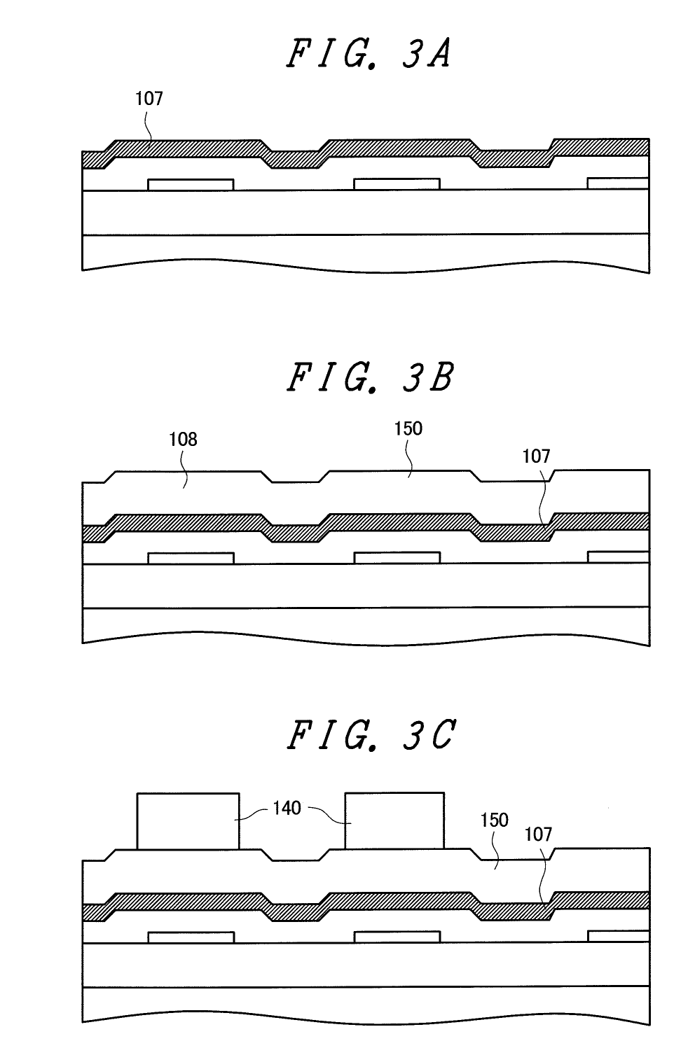

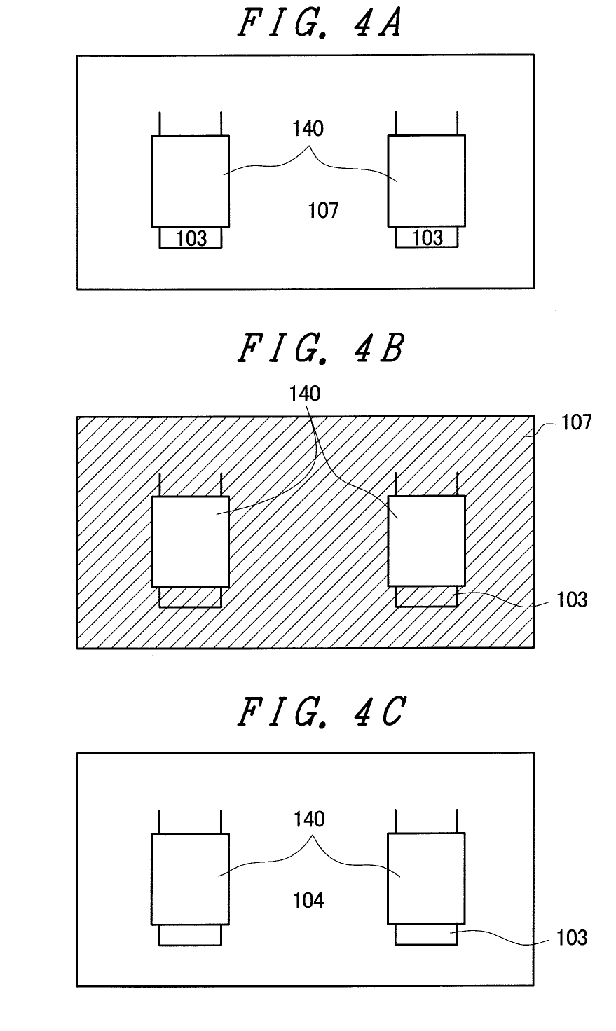

As shown in FIG. 3A, due to the radiation of laser beams to the a-Si layer 108, the a-Si layer 108 is formed into the poly-Si layer 107. On the poly-Si layer 107 formed in this manner, as shown in FIG. 3B, an SiO-based film is formed for forming the channel stopper layer 150. Then, a photolithography process is performed for forming the channel stopper layers 150 and the poly-Si layer 107 into desired shapes respectively. FIG. 3C shows a state in which a photo resist 140 is formed on the channel stopper layer 150 by a photolithography step. FIG. 4A is a plan view showing a state in which the photo resist 140 is formed on the channel stopper layer 150.

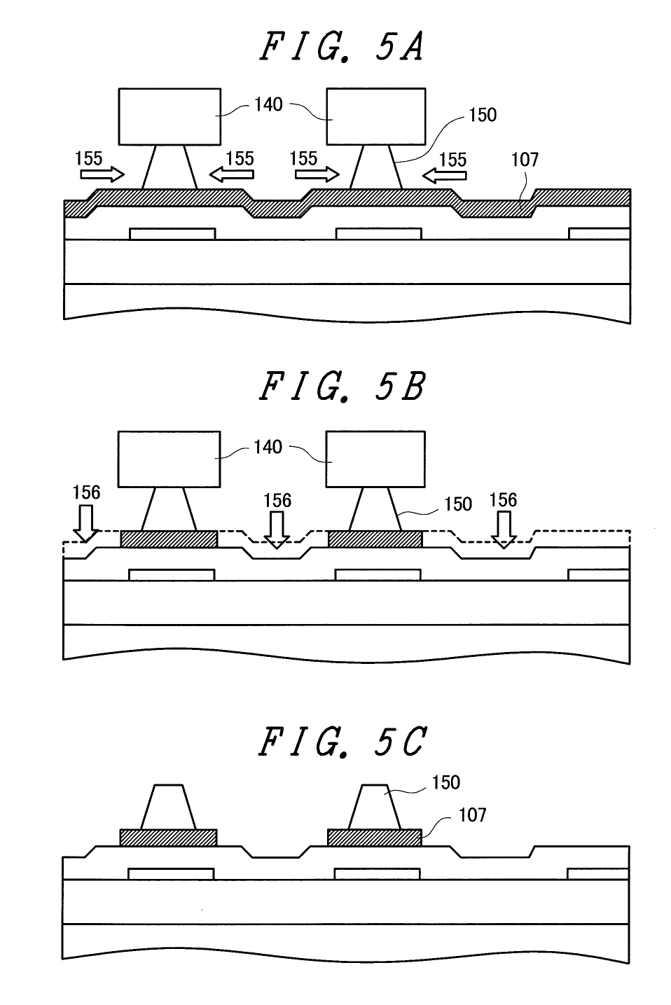

In such a state, wet etching is performed using a hydrofluoric-acid-based chemical thus forming the channel stopper layer 150 into a desired shape. Side etching 155 is applied to the channel stopper layer 150 by over-etching thus shrinking the channel stopper layer 150 smaller than a resist pattern. Such a state is shown in FIG. 5B. Since the poly-Si layer 107 is disposed below the channel stopper layer 150, the poly-Si layer 107 is not etched. In FIG. 4B which is a plan view, the poly-Si layer 107 is exposed outside at portions thereof other than a portion thereof which is covered with the photo resist 140.

In a state shown in FIG. 5A, the poly-Si layer 107 is formed by dry etching. In performing dry etching, since there is no side etching, as indicated by an arrow 156 shown in FIG. 5B, the poly-Si layer 107 is formed in the same shape as a resist pattern by dry etching. FIG. 4C is a plan view corresponding to the constitution shown in FIG. 5B. In FIG. 4C, portions of the poly-Si layer 107 other than a portion of the poly-Si layer 107 covered with the photo resist 140 are removed thus exposing the gate insulation film at such portions.

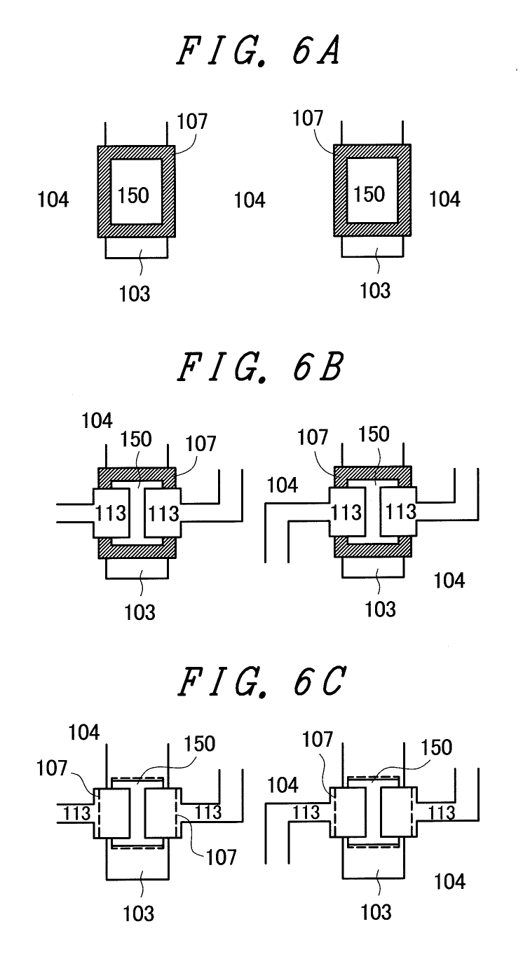

Then, the photo resist 140 is removed. FIG. 5C shows a state in which the photo resist 140 is removed. FIG. 6A is a view corresponding to the plan view of the constitution shown in FIG. 5B. As shown in FIG. 5C and FIG. 6A, on the periphery of the poly-Si layer 107, a region which is not covered with the channel stopper layer 150 exists. This peripheral portion constitutes a contact portion which is brought into contact with the SD electrode 113 or the n+Si layer 109 which is formed later. Accordingly, the ON resistance is decreased thus increasing a quantity of an ON current.

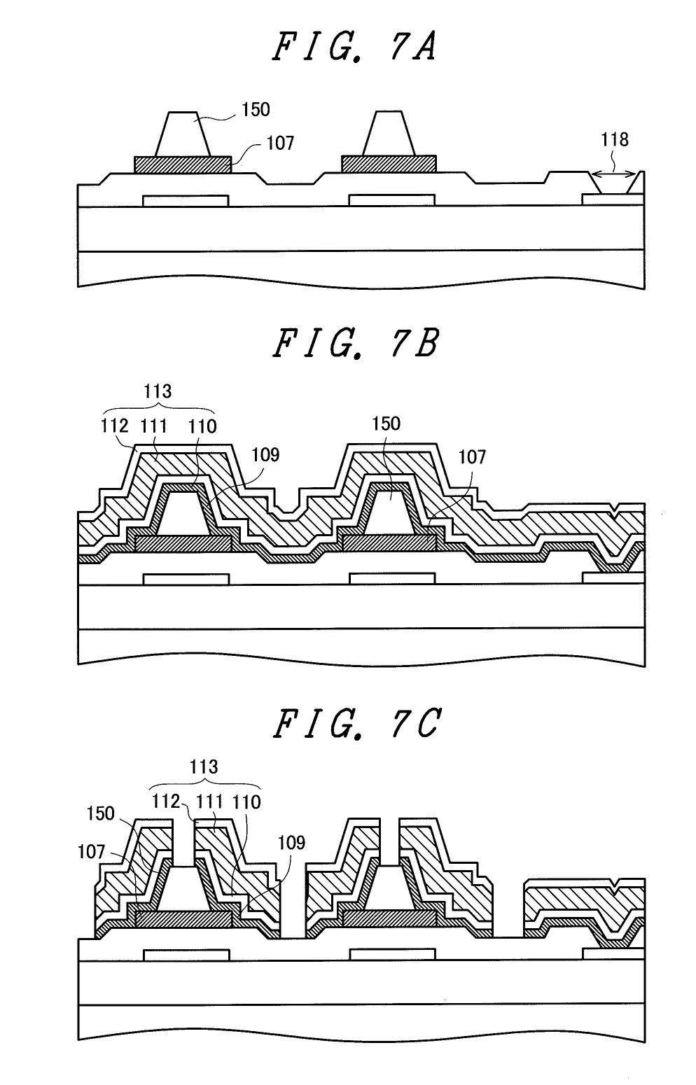

Then, the gate insulation film of the terminal part is removed so as to form a contact hole 118 in the terminal part thus exposing the gate line which extends to the terminal part. Thereafter, the n+Si layer 109 doped with phosphorous is formed by a plasma CVD method. Subsequently, the SD electrode 113 is formed by sputtering. The SD electrode layer 113 is formed on the same layer as the data signal line. As shown in FIG. 7B, the SD electrode layer 113 is constituted of three layers consisting of the barrier metal layer 110, the aluminum layer 111 and the cap metal layer 112. The barrier metal layer 110 and the cap metal layer 112 are made of molybdenum. Although the electrical conduction or connection of the SD electrode 113 is mainly allocated to aluminum, molybdenum is used for preventing hillock of aluminum or for preventing contact failure attributed to the oxidation of aluminum when aluminum and ITO are brought into contact with each other.

Next, as shown in FIG. 7C, the SD electrode 113 and the n+Si layer 109 are formed into desired shapes by a photolithography step and an etching step. First of all, three layers consisting of the barrier metal layer 110, the aluminum layer 111 and the cap metal layer 112 are formed into desired shapes by wet etching. Then, using the SD line layer as a mask, the n+Si layer 109 and the poly-Si layer 107 are formed into desired shapes by dry etching. FIG. 6B shows a state in which the n+Si layer 109 is removed in the course of this dry etching, wherein the poly-Si layer 107 and the gate insulation film are shown in an exposed state.

Next, using the SD electrode 113 and the channel stopper layer 150 as masks, dry etching is continued so as to form the poly-Si layer 107 into a desired shape. Due to such dry etching, the poly-Si layer 107, as shown in FIG. 6C, exists only below the channel stopper layer 150 and below the SD line. A dotted line in FIG. 6C shows the region where the poly-Si layer 107 exists. Due to the above-mentioned steps, the bottom-gate-type poly-Si TFT is formed.

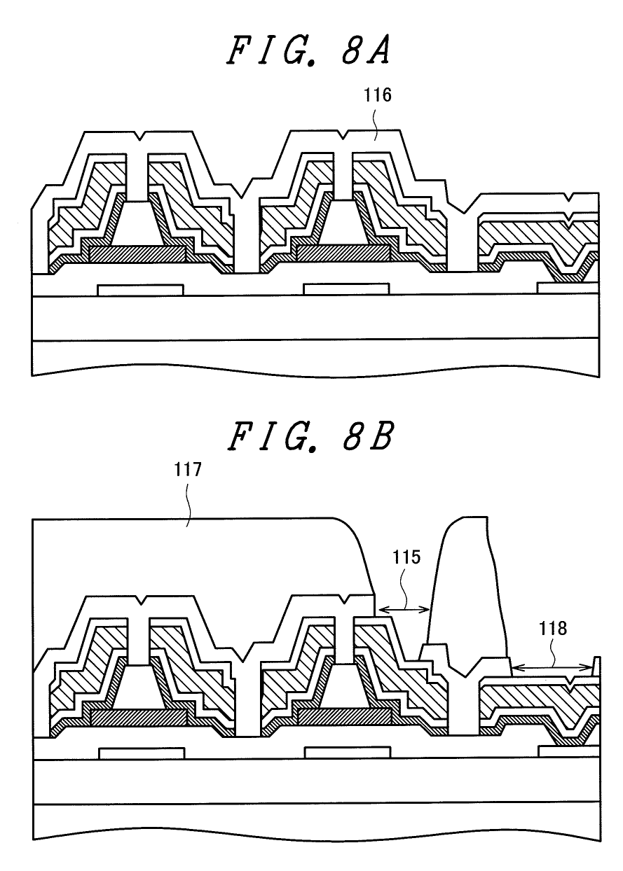

Next, as shown in FIG. 8A, the whole TFT is covered with the passivation film 116 made of SiN. The passivation film 116 made of SiN is formed by a plasma CVD method. Then, as shown in FIG. 8B, a photosensitive organic film 117 is applied to the passivation film 116 for leveling by coating, and the organic film 117 is formed into a desired shape by a photolithography step. A film thickness of the organic film 117 is approximately 1 to 2 μm. Using the organic film 117 as a mask, the passivation film 116 made of SiN is etched thus forming the through hole 115. The contact hole 118 in the terminal part is formed simultaneously with the through hole 115 in the pixel electrode 119 portion by the same process.

Then, an ITO film for forming the pixel electrode 119 is formed by sputtering, and the ITO film is formed into a desired shape by photo etching thus forming the pixel electrode 119. Simultaneously with the formation of the pixel electrode 119 using the ITO film, an ITO film is also formed in the terminal part. In this manner, the TFT substrate shown in FIG. 1 is formed.

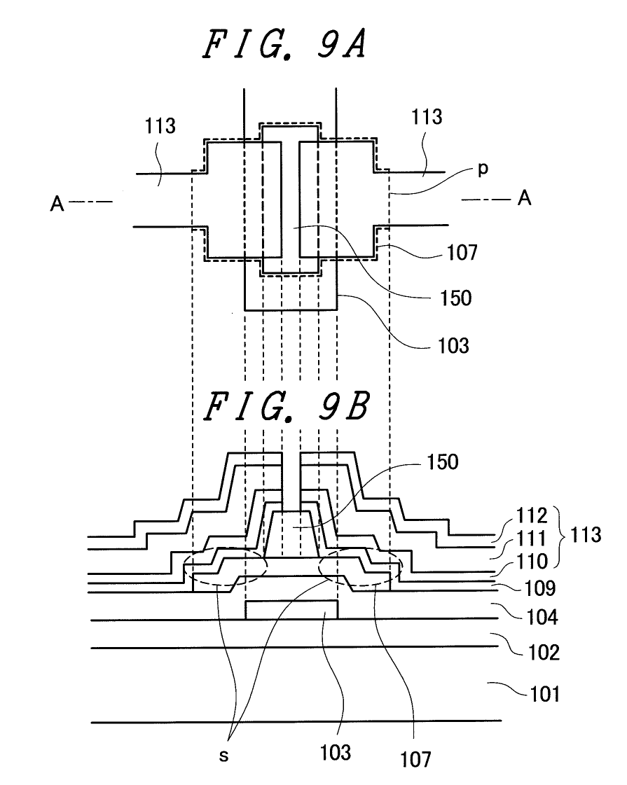

FIG. 9 shows the detail of only a portion of the TFT which is formed in this manner. In FIG. 9, the region of the poly-Si layer 107 is formed in a slightly enlarged manner compared to the corresponding region shown in FIG. 1. However, there is no fundamental difference between the constitution of the TFT shown in FIG. 1 and the constitution of the TFT shown in FIG. 9, and the present invention is applicable to both cases without causing any problem. FIG. 9A is a plan view of the TFT, and FIG. 9B is a cross-sectional view taken along a line A-A in FIG. 9A. In FIG. 9A, the poly-Si layer 107 exists in a portion surrounded by a broken line p. As shown in FIG. 9B, the poly-Si layer 107 and the n+Si layer 109 are brought into contact with each other at a large planar portion s. Since a contact area between the poly-Si layer 107 and the n+Si layer 109 is large, there is no possibility that the resistance at such a portion adversely influences an ON current. Accordingly, a quantity of ON current can be increased.

### Embodiment 2

In this embodiment, the pixel-use TFT is an a-Si TFT of a bottom gate type, and the drive-circuit-use TFT is a poly-Si TFT of a bottom gate type. Here, the a-Si TFT is a TFT in which a semiconductor layer is formed using a-Si, and the poly-Si TFT is a TFT in which a semiconductor layer is formed using poly-Si. The poly-Si TFT which exhibits large mobility thus operating at a high speed is advantageous in the drive circuit part, and the a-Si TFT which can easily decrease a leak current is advantageous in the pixel part.

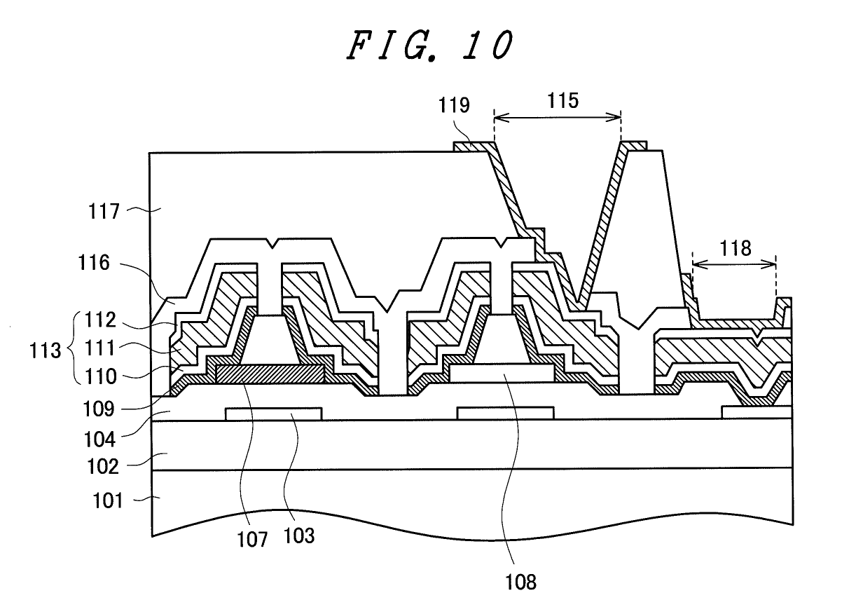

FIG. 10 is a schematic cross-sectional view showing the constitution of a portion of the liquid crystal display device of the embodiment 2 according to the present invention. In FIG. 10, the left-side TFT is a drive-circuit-use TFT, and a semiconductor layer of the TFT is made of poly-Si. Since the drive-circuit-use TFT requires a high-speed operation, the TFT in which the semiconductor layer is formed using poly-Si is used. The right-side TFT is a pixel-use TFT, and a semiconductor layer of the TFT is made of a-Si. This is because a small leak current is more important than a high speed operation in the pixel-use TFT.

A terminal part is formed on a further right side of the pixel-use TFT. In FIG. 1, to make a clear comparison of the drive-circuit-use TFT, the pixel-use TFT and the terminal part, these elements are described such that these elements are arranged adjacent to each other. However, in an actual display device, the respective elements are formed remote from each other. In FIG. 10, except for the constitution that the semiconductor layer of the pixel-use TFT is made of a-Si, the embodiment 1 and the embodiment 2 are substantially equal in other constitutions and hence, the explanation of other constitutions is omitted.

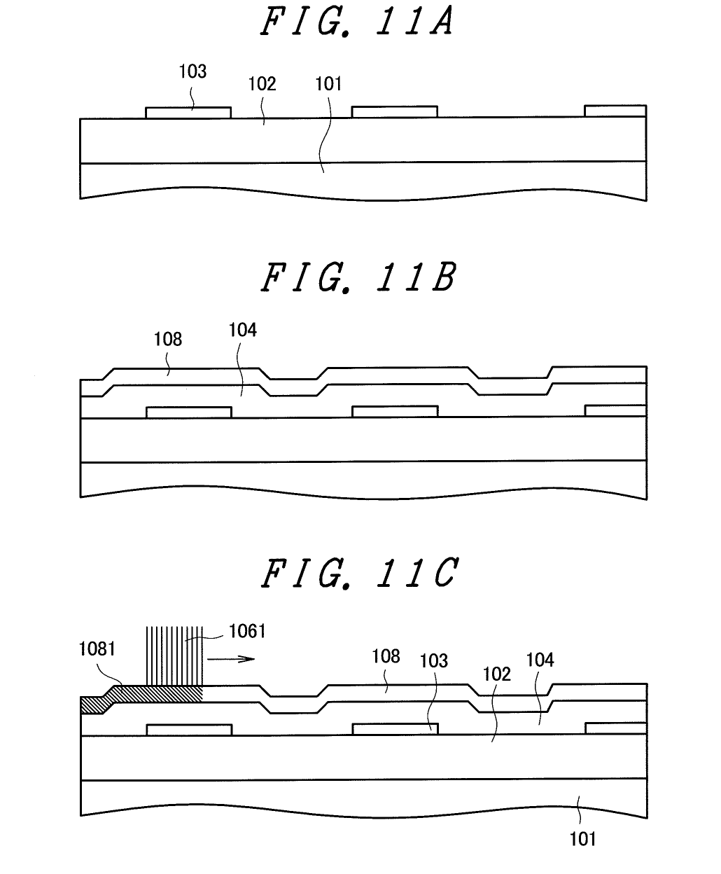

FIG. 11A to FIG. 14C show a process of forming the TFTs and the terminal part shown in FIG. 10. As shown in FIG. 11A, a background film 102 made of SiN is formed on a TFT substrate 101 by a plasma CVD method. Thereafter, a line layer for forming a gate electrode 103 is formed as a film by sputtering, and the line layer is formed into a desired shape by a photolithography step. The gate electrode 103 is formed using a high-melting-point material (Mo-based material) by taking a laser annealing step performed following this step into consideration.

As shown in FIG. 11B, an SiO2 film for forming a gate insulation film 104 is formed by a plasma CVD method and, subsequently, an a-Si film is formed by a plasma CVD method. In the drive circuit part, the a-Si film is transformed into a poly-Si film by laser annealing. Although an excimer laser is used as a laser, a film thickness which allows the transformation of a-Si into poly-Si using the excimer laser is limited. That is, the film thickness is limited to 70 nm or below. Further, a thickness of the typical a-Si film in this embodiment is 50 nm. In this embodiment, the semiconductor layer of the poly-Si TFT and the portion of the semiconductor of the a-Si TFT are formed by the same process and hence, both of a thickness of an a-Si layer 108 and a thickness of a poly-Si layer 107 are set to 50 nm.

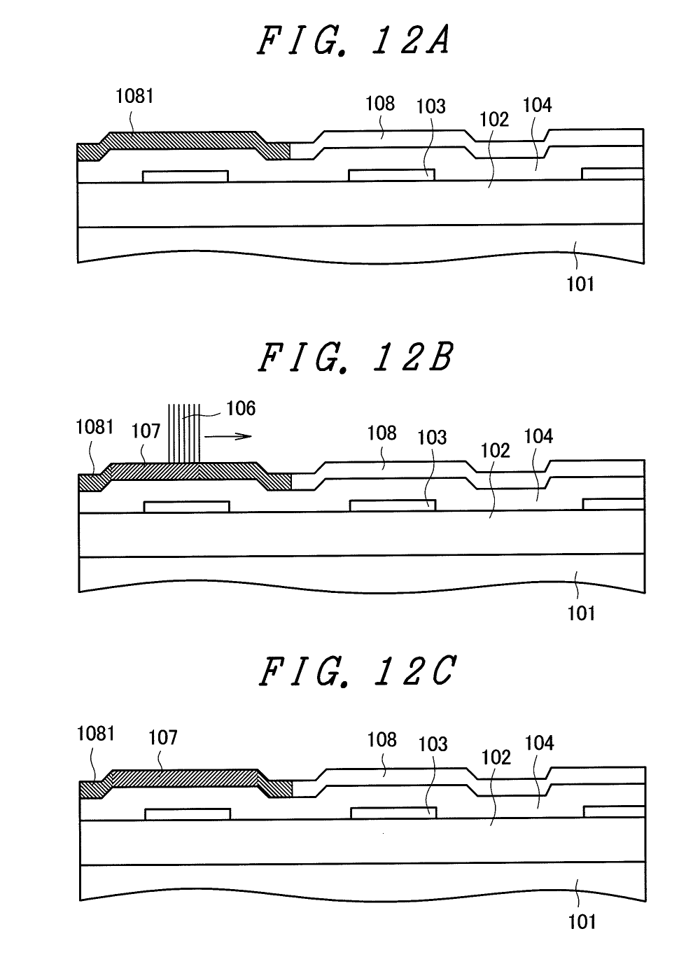

After forming the a-Si film, as shown in FIG. 11C, laser beams 1061 are radiated to only the a-Si film at a portion corresponding to the drive circuit part thus heating the portion of the a-Si film to a temperature of approximately 450° C. so as to perform dehydrogenation. This dehydrogenation is performed for preventing bumping of hydrogen in annealing for crystallizing the portion of the a-Si film corresponding to the drive circuit part which is performed later. Due to such steps, as shown in FIG. 12A, the a-Si layer 108 which is held in a deposited state and a dehydrogenated a-Si-layer region 1081 coexist.

Then, as shown in FIG. 12B, laser beams are radiated to the dehydrogenated a-Si-layer region 1081 in a region corresponding to the drive circuit part to which dehydrogenation is applied so as to transform the a-Si film into the poly-Si film. In this manner, as shown in FIG. 12C, on one substrate, a semiconductor film having regions where the poly-Si layer 107 is formed and regions where the a-Si layer 108 is formed are formed. As shown in FIG. 12C, the a-Si film 1081 to which the dehydrogenation is applied remains on the periphery of the region where the poly-Si film is formed. To prevent bumping of hydrogen in transforming the a-Si film into the poly-Si film by laser treatment, the dehydrogenated region is set larger than the poly-Si layer thus ensuring tolerance in the process.

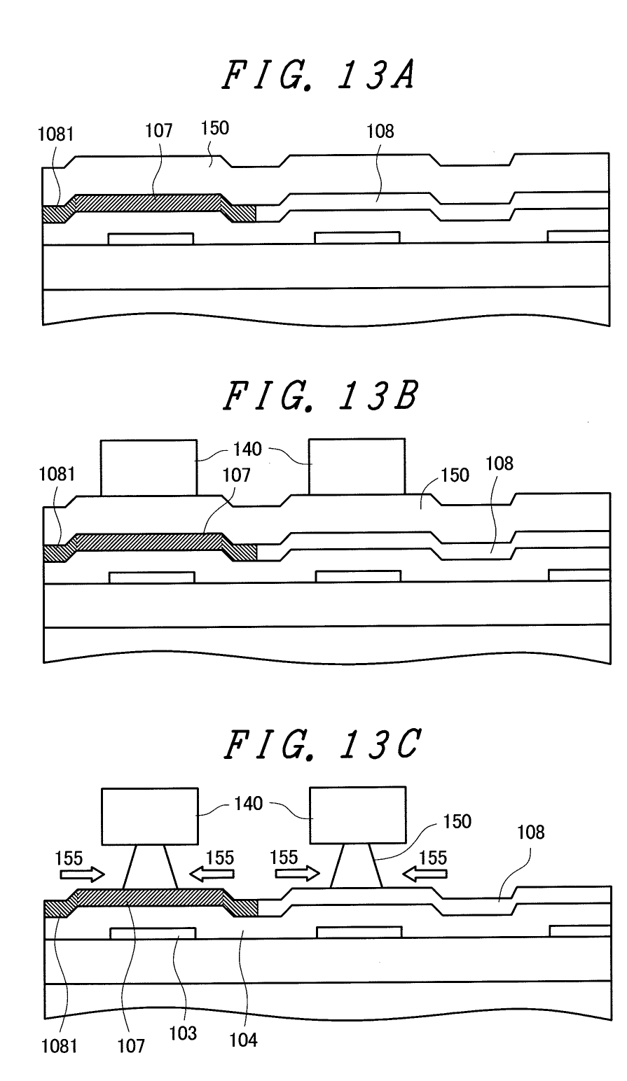

Then, as shown in FIG. 13A, an SiO-based film which constitutes a channel stopper layer 150 is formed over the whole surface of the substrate. Subsequently, a photolithography process is performed for forming the channel stopper layers 150 and the poly-Si layer 107 into desired shapes respectively. FIG. 13B shows a state in which a photo resist 140 is formed on the channel stopper layer 150 by a photolithography step.

In such a state, wet etching is performed using a hydrofluoric-acid-based chemical thus forming the channel stopper layer 150 into a desired shape. Side etching 155 is applied to the channel stopper layer 150 by over-etching thus shrinking the channel stopper layer 150 smaller than a resist pattern. Such a state is shown in FIG. 13C. This forming is applied in common to the poly-Si region and the a-Si region. Since the poly-Si layer 107 or the a-Si layer 108 is disposed below the channel stopper layer 150, the poly-Si layer 107 or the a-Si layer 108 is not etched.

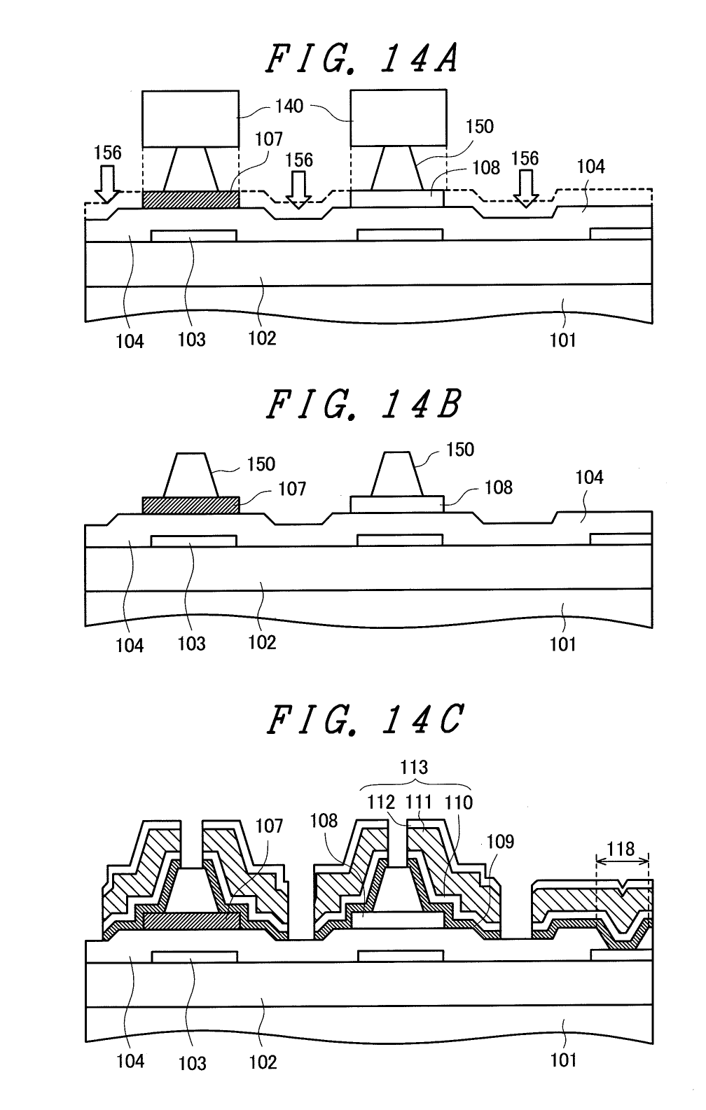

In a state shown in FIG. 13C, the poly-Si layer 107 and the a-Si layer 108 are formed by dry etching. Since there is no side etching, as indicated by an arrow 156 shown in FIG. 14A, the poly-Si layer 107 and the a-Si layer 108 are formed in the same shape as a resist pattern by dry etching.

Then, the photo resist 140 is removed. FIG. 14B shows a state in which the photo resist 140 is removed. As shown in FIG. 14B, on the periphery of the poly-Si layer 107 and on the periphery of the a-Si layer 108, a region which is not covered with the channel stopper layer 150 exists. This peripheral portion constitutes a contact portion which is brought into contact with the SD electrode 113 which is formed later. Accordingly, the ON resistance is decreased thus increasing a quantity of ON current.

Usually, the a-Si TFT adopts the channel etching structure in place of the channel stopper 150. This is because, in the usual a-Si TFT, a film thickness of a-Si layer 108 is large enough to allow channel etching. However, the a-Si TFT of this embodiment has a film thickness of approximately 50 nm, that is, the a-Si TFT of this embodiment cannot have a large film thickness and hence, the a-Si TFT of this embodiment adopts the channel stopper 150 structure.

Here, although not shown in the drawing, the gate insulation film of the terminal part is removed so as to form a contact hole 118 in the terminal part thus exposing the gate line which extends to the terminal part.

Thereafter, the n+Si layer 109 doped with phosphorous is formed by a plasma CVD method. Subsequently, the SD electrode 113 is formed by sputtering. The SD electrode layer 113 is constituted of three layers consisting of the barrier metal layer 110, the aluminum layer 111 and the cap metal layer 112. The SD electrode 113 of this embodiment has the same structure as the embodiment 1 explained previously.

Next, as shown in FIG. 14C, the SD electrode 113 and the n+Si layer 109 are formed into desired shapes by a photolithography step and an etching step. First of all, three layers consisting of the barrier metal layer 110, the aluminum layer 111 and the cap metal layer 112 are formed into desired shapes by wet etching. Then, using the SD line layer as a mask, the n+Si layer 109 and the poly-Si layer 107 or the a-Si layer 108 and the poly-Si layer 107 are formed into desired shapes respectively by dry etching.

Due to such dry etching, the poly-Si layer 107 or the a-Si layer 108 exists only below the channel stopper layer 150 and below the SD line. Due to the above-mentioned steps, the bottom-gate-type poly-Si TFT using and the bottom-gate-type a-Si TFT are formed.

Next, the whole TFT is covered with the passivation film 116 made of SiN. The passivation film 116 made of SiN is formed by a plasma CVD method. Then, a photosensitive organic film 117 is applied to the passivation film 116 for leveling by coating, and the organic film 117 is formed into a desired shape by a photolithography step. A film thickness of the organic film 117 is approximately 1 to 2 μm. Using the organic film 117 as a mask, the passivation film 116 made of SiN is etched thus forming the through hole 115. The contact hole 118 in the terminal part is formed simultaneously with the through hole 115 in the pixel electrode 119 by the same process.

Then, an ITO film for forming the pixel electrode 119 is formed by sputtering, and the ITO film is formed into a desired shape by photo etching thus forming the pixel electrode 119. Simultaneously with the formation of the pixel electrode 119 using the ITO film, an ITO film is also formed in the terminal part. In this manner, the TFT substrate shown in FIG. 10 is formed.

As has been explained heretofore, according to the above-mentioned embodiments, the poly-Si-type TFT and the a-Si-type TFT can be simultaneously formed by the same process. Further, it is possible to form the poly-Si-type TFT having the large ON current value and the a-Si-type TFT having the small OFF current value, that is, the TFTs which maintain the respective unique characteristics on the same substrate.

What is claimed is:

1. A liquid crystal display device including a display region in which pixel electrodes and thin film transistors are formed in a matrix array and a drive circuit which is formed on the periphery of the display region and includes a thin film transistor therein, wherein
the thin film transistors are configured such that a gate insulation film is formed so as to cover a gate electrode, a poly-Si layer is formed on the gate insulation film, a channel stopper layer is formed on a main surface of the poly-Si layer except for a peripheral portion of the main surface of the poly-Si layer, an n+Si layer is in contact with the peripheral portion of the main surface of the poly-Si layer, and a source/drain electrode is formed so as to cover the n+Si layer.

2. A liquid crystal display device according to claim 1, wherein the n+Si layer and the source/drain electrode cover a portion of the channel stopper layer.

3. A liquid crystal display device including a display region in which pixel electrodes and pixel-use thin film transistors are formed in a matrix array and a drive circuit which is formed on the periphery of the display region and includes a drive-circuit-use thin film transistor, wherein
the drive-circuit-use thin film transistor and the pixel-use thin film transistors are configured such that a gate insulation film is formed so as to cover a gate electrode, a semiconductor layer is formed on the gate insulation film, a channel stopper layer is formed on a main surface of the semiconductor layer except for a peripheral portion of the main surface of the semiconductor layer, an n+Si layer is in contact with the peripheral portion of the main surface of the semiconductor layer, a source/drain electrode is formed so as to cover the n+Si layer, the semiconductor layer of the drive-circuit-use thin film transistor is formed using poly-Si, and the semiconductor layer of the pixel-use thin film transistor is formed using a-Si.

4. A liquid crystal display device according to claim 3, wherein a film thickness of the a-Si film is 70 nm or below.

5. A liquid crystal display device according to claim 3, wherein the n+Si layer and the source/drain electrode cover a portion of the channel stopper layer.

6. A liquid crystal display device including a display region in which pixel electrodes and thin film transistors are formed in a matrix array and a drive circuit which is formed on the periphery of the display region and includes a thin film transistor therein, wherein
the thin film transistors are configured such that a gate insulation film is formed so as to cover a gate electrode, a poly-Si layer is formed on the gate insulation film, a channel stopper layer is formed on the poly-Si layer, and an n+Si layer and a source/drain electrode are formed so as to cover the channel stopper layer and a portion of the poly-Si layer,
the channel stopper layer is formed into a desired shape by wet etching,
the poly-Si layer is formed into a desired shape by dry etching, and
an edge portion of the poly-Si layer formed into a desired shape by dry etching is arranged outside an edge portion of the channel stopper layer formed into a desired shape by wet etching.

7. A liquid crystal display device according to claim 6, wherein the n+Si layer is formed into a desired shape by dry etching.
